(19) United States
(12) Patent Application Publication
(10) Pub. No.: US 2016/0087116 A1
(43) Pub. Date: Mar. 24, 2016

(54) DISPLAY DEVICE INTEGRATED WITH SOLAR CELL PANEL AND METHODS FOR PRODUCING THE SAME

(71) Applicant: 3M INNOVATIVE PROPERTIES COMPANY, St. Paul, MN (US)

(72) Inventors: Jingfei CHEN, Shanghai (CN); Guanglei DU, Beijing (CN); Chao TENG, Shanghai (CN)

(73) Assignee: 3M INNOVATIVE PROPERTIES COMPANY, St. Paul, MN (US)

(21) Appl. No.: 14/888,743

(22) PCT Filed: May 5, 2014
(86) PCT No.: PCT/US2014/036735

§ 371 Date: Nov. 3, 2015

(30) Foreign Application Priority Data
May 6, 2013 (CN) 201310168102.X

(51) Int. Cl. H01L 31/0232; H01L 33/50; H01L 27/15; H01L 31/16

(52) U.S. Cl. CPC H01L 31/02322; H01L 31/16; H01L 33/504; H01L 27/156

(57) ABSTRACT

The present invention discloses a solar cell panel integrated on a display unit, a display device integrated with the solar cell panel and methods for producing the same. The solar cell panel integrated on a display unit according to the present invention comprises a photoelectric material layer with RGB colors comprising red units, green units and blue units, wherein the red units, green units and blue units are arranged corresponding to pixel arrays in the display unit, and one or two of the red units, green units and blue units are made of the photoelectric active material. The photoelectric active material layer with RGB colors according to the present invention can replace a common color filter.

### TECHNICAL FIELD

The present invention relates to a technology field of display devices, and in particular, to a solar cell panel integrated on a display unit, a display device integrated with the solar cell panel and methods for producing the same.

### BACKGROUND ART

Portable devices, such as laptops, tablets, mobile phones and the like are widely used in our daily life. However, the use duration of these portable devices are largely limited due to the very restrictive battery life. Especially in situations where power source is not available, the portable devices can't be charged when running out of power.

At present, a solar cell can be used for solving the above problem. When a portable device runs out of power, a peripheral solar cell can supply as a power source and make it continue working. However, carrying peripheral solar cells is inconvenient for portable device users. Therefore combining a solar cell with a portable device allows the great improvement in portability. Since the surface of most portable devices is occupied by a large-sized display screen, many efforts have been taken on adding a solar cell layer in the display device. However, a solar cell layer, including so-called transparent one, has a certain color. Therefore, the solar cell layer when provided on the display device will absorb visible light and influence the display performance. In addition, color filters in conventional display devices will absorb ⅔ of the energy from back light so as to exhibit the corresponding color. The absorbed back light energy will be converted into heat or any other energy such that a large proportion of back light energy is wasted.

US 2010/0245731 discloses a photovoltaic cell having a size same as that of subpixel, as shown in FIG. 1. This photovoltaic cell is provided on the pixel of the display device. This photovoltaic cell uses different photoelectric active materials to absorb light of different wavelengths so as to function like a color filter. However, in order to function like a color filter, it is necessary to provide in the photovoltaic cell a plurality of absorbing layers for absorbing light of different wavelengths, which will result in a high cost and complex process. In addition, since blue and green absorbing layers have poorer color representability, it is necessary to further provide a common color filter in the display device in order to ensure normal color representability of the display device.

### DISCLOSURE OF THE INVENTION

An object of the present invention is to provide a solar cell panel integrated on a display unit, which can convert a portion of absorbed unnecessary backlight and ambient light entered into a display device from outside into electric power while functioning as a filter for replacing a conventional color filter.

Another object of the present invention is to provide a display device comprising a display unit and the solar cell panel of the present invention.

A further object of the present invention is to provide methods for producing the above solar cell panel and display device, which can simplify the process of producing the display device integrated with solar cell panel, improve the productivity and reduce the ratio of defective products.

The above objects of the present invention are achieved by the following technical solutions.

That is, a first aspect of the present invention relates to a solar cell panel integrated on a display unit, comprising: a photoelectric material layer with RGB colors comprising red units, green units and blue units, wherein the red units, green units and blue units are arranged corresponding to pixel arrays in the display unit, and one or two of the red units, green units and blue units are made of a photoelectric active material.

In the present invention, the arranging manner of the red units, green units and blue units in the photoelectric material layer, that is, arranging the red units, green units and blue units corresponding to pixel arrays in the display unit, is same as that of the red, green and blue units (subpixels) in a conventional color filter. Because of the use of a photoelectric active material layer with RGB colors constructed as a conventional color filter, the obtained solar cell panel can function like a color filter, so that it allows the omission of a color filter layer in the display device and in turn simplifies the process and saves the cost; and it can convert a portion of absorbed unnecessary backlight and ambient light entered into the display device from outside into electric power while functioning as a color filter.

Preferably, the present invention provides a solar cell panel integrated on a display unit, comprising:

a photoelectric material layer with RGB colors comprising red units, green units and blue units, wherein the red units, green units and blue units are arranged corresponding to pixel arrays in the display unit, and the red units are made of a photoelectric active material;

a first transparent substrate layer and a second transparent substrate layer provided at the two sides of the photoelectric material layer, respectively;

a transparent electrode layer provided between the first transparent substrate layer and the photoelectric material layer; and

a hole transmission layer provided between the second transparent substrate layer and the photoelectric material layer,

Preferably, the solar cell panel further comprises a metal grid layer provided between the hole transmission layer and the second transparent substrate layer, at a position corresponding to the boundaries between the red units, green units and blue units.

A second aspect of the present invention relates to a display device comprising a display unit and the solar cell panel according to the present invention.

Since the photoelectric material layer can function like a color filter at the same time, a conventional color filter layer can be omitted in the display device of the present invention.

The display device of the present invention may further comprise a black matrix which can be provided at any suitable position in the display device, e.g. in the photoelectric material layer of the solar cell panel.

The black matrix of the present invention can be made of a photoelectric active material. When the black matrix is made of a photoelectric active material, its color is not a common black, but the arranging manner thereof is the same as that of a conventional black matrix. In order to indicate the relationship relative to a conventional black matrix, the term “black matrix” is still used in the present invention. The black matrix made of a photoelectric active material allows the increase of the effective area of the photoelectric active material layer and thus effective increase of photoelectric conversion capability.

The black matrix can also be made of a conductive material coated with an insulating adhesive. The insulating adhesive can be selected from any known adhesive system having good insulating property, preferably but not limited to, an acrylate-based, an epoxy-based or a polyurethane-based adhesive system, etc. The conductive material can be selected from any known conductive metal, preferably but not limited to, copper, aluminum, iron, gold, silver, etc.

A third aspect of the present invention relates to a method for producing the solar cell panel of the present invention, comprising the steps of: forming a transparent electrode layer on a first transparent substrate; depositing a layer of red photoelectric active material on the transparent electrode layer; then removing the red photoelectric active material at the sites of blue units and green units and filling blue and green resist materials at the corresponding positions; after that, coating a layer of hole transmission material; and finally forming a second transparent substrate with a transparent insulating material.

Preferably, the method for producing the solar cell panel of the present invention comprises the steps of: forming a transparent electrode layer on a first transparent substrate; depositing a layer of red photoelectric active material on the transparent electrode layer; then removing the red photoelectric active material at the sites of blue units and green units and filling blue and green resist materials at the corresponding positions; after that, coating a layer of hole transmission material; then depositing a layer of metal grid; and finally forming a second transparent substrate with a transparent insulating material.

A fourth aspect of the present invention relates to a method for producing the display device of the present invention, comprising affixing the solar cell panel of the present invention onto the display unit, wherein the solar cell panel is affixed to the display unit at a side of the first transparent substrate layer or second transparent substrate layer.

In the present invention, since the solar cell panel is located on a surface of the display unit, the solar cell layer and display panel layer can be separately produced such that the ratio of defective products in the production can be effectively reduced.

### DESCRIPTION OF THE DRAWINGS

FIG. 1 is a cross-sectional schematic view of a liquid crystal display device with a photovoltaic cell according to the prior art, wherein 190 represents the photovoltaic cell unit;

FIG. 2 is a schematic view 200 of a structure of a common display panel in the prior art with backlight 210,

wherein the layers from bottom to top are: bottom polarizing plate 201, bottom glass 202, electrode 203, liquid crystal layer 204, electrode 205, color filter 206, top glass 207, and top polarizing plate 208, in this order;

FIG. 3 is a schematic top view 300 of a structure of a color filter in a common display panel in the prior art,

wherein the vertical lines-marked blocks, oblique lines-marked blocks and transverse lines-marked blocks represent the red 301, green 302 and blue 303 blocks, respectively;

FIG. 4 is a schematic view 400 of a structure of a display device with the solar cell panel according to one embodiment of the present invention,

wherein the layers from bottom to top are: bottom polarizing plate 401, bottom glass 402, electrode 403, liquid crystal layer 404, electrode 405, black matrix 406, top glass 407, top polarizing plate 408, substrate 409, ITO layer 410, photoelectric active layer 411, hole transmission layer 412, and substrate 413, in this order;

FIG. 5 is a schematic top view 500 of the black matrix in FIG. 4;

FIG. 6 is a schematic top view 600 of the photoelectric active layer in FIG. 4,

wherein the vertical lines-marked blocks, oblique lines-marked blocks and transverse lines-marked blocks represent the red 601, green 602 and blue 603 blocks, respectively;

FIG. 7 is a schematic view of a bulk heterojunction structure 700 and an inverted bulk heterojunction structure 750 of an organic solar cell. Structure 700 has substrate 701, ITO layer 702, P3HT:PC61BM layer 703, PEDOT:PSS layer 704, and substrate 705. Structure 750 has substrate 751, ITO layer 752, PEDOT:PSS layer 753, P3HT:PC61BM layer 754, metal cathode layer 755 and substrate 756;

FIG. 8 is a schematic view of the production flow process of the solar cell panel of the present invention;

FIG. 9 is a schematic view 900 of a structure of a display device with the solar cell panel according to another embodiment of the present invention (the black matrix is located on the bottom substrate of the display unit),

wherein the layers from bottom to top are: bottom polarizing plate 901, bottom glass 902, electrode 903, black matrix 904, liquid crystal layer 905, electrode 906, top glass 907, top polarizing plate 908, substrate 909, ITO layer 910, photoelectric active layer 911, hole transmission layer 912, and substrate 913, in this order;

FIG. 10 is a schematic view 1000 of a structure of a display device with the solar cell panel according to another embodiment of the present invention (the black matrix is located on a top surface of the bottom substrate of the solar cell panel),

wherein the layers from bottom to top are: bottom polarizing plate 1001, bottom glass 1002, electrode 1003, liquid crystal layer 1004, electrode 1005, top glass 1006, top polarizing plate 1007, substrate 1008, black matrix 1009, ITO layer 1010, photoelectric active layer 1011, hole transmission layer 1012 and substrate 1013, in this order;

FIG. 11 is a schematic view 1100 of a structure of a display device with the solar cell panel according to another embodiment of the present invention (the active layer contains a black matrix),

wherein the layers from bottom to top are: bottom polarizing plate 1101, bottom glass 1102, electrode 1103, liquid crystal layer 1104, electrode 1105, top glass 1106, top polarizing plate 1107, substrate 1108, ITO layer 1109, photoelectric active layer 1110 (containing a black matrix), hole transmission layer 1111, and substrate 1112, in this order;

FIG. 12 is a schematic view 1200 of a structure of a solar cell panel according to another embodiment of the present invention (in a parallel connection manner),

wherein the layers from bottom to top are: transparent substrate layer 1201, transparent conductive layer 1202 (hole transmission layer), black matrix 1203, transparent conductive layer 1204 (transparent electrode layer), and transparent substrate layer 1205, in this order, wherein, the transparent conductive layer 1204 (transparent electrode layer) is continuous, and the transparent conductive layer 1202 (hole transmission layer) is also continuous.

FIG. 13 is a schematic view 1300 of a structure of the black matrix according to another embodiment of the present invention where the solar cell panels are connected in parallel,

wherein 1301 is an insulating adhesive and 1302 is a conductive material.

FIG. 14 is a schematic view 1400 of a structure of a solar cell panel according to another embodiment of the present invention (connected in series),

wherein the layers from bottom to top are: transparent substrate layer 1401, transparent conductive layer 1402 (hole transmission layer), black matrix 1403, transparent conductive layer 1404(transparent electrode layer), and transparent substrate layer 1405, in this order, wherein, the transparent conductive layer 1404 (transparent electrode layer) is non-continuous, separated intermittently by the insulating adhesive in the transparent conductive layer 1404 near the black matrix, and the transparent conductive layer 1402 (hole transmission layer) is also non-continuous, separated intermittently by the insulating adhesive in the transparent conductive layer 1402 near the black matrix.

FIG. 15 is a schematic view 1500 of a structure of the black matrices according to another embodiment of the present invention where the solar cell panels are connected in series,

wherein 1501 is an insulating adhesive and 1502 is a conductive material.

### BEST MODES FOR CARRYING OUT THE INVENTION

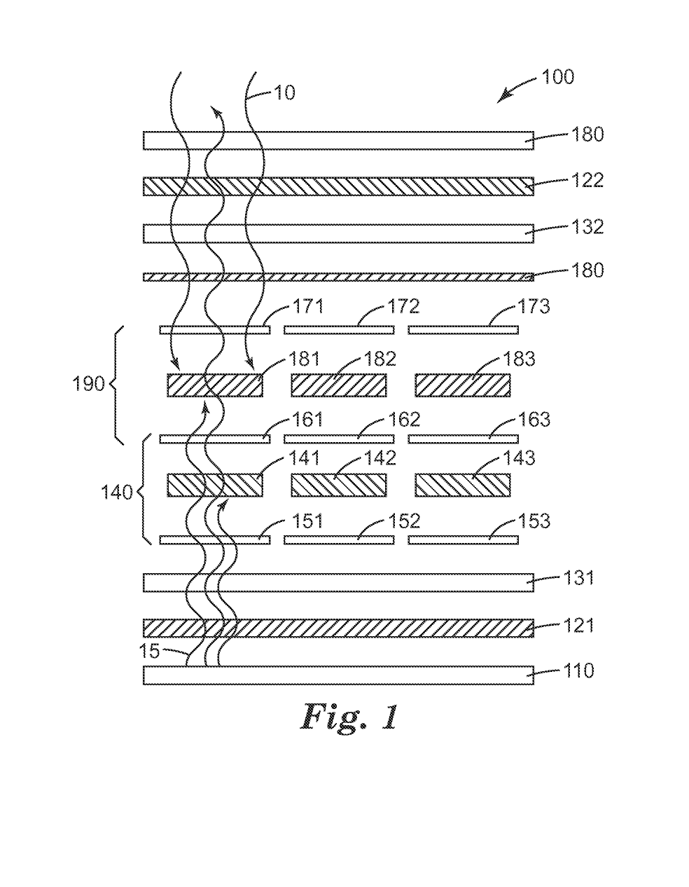

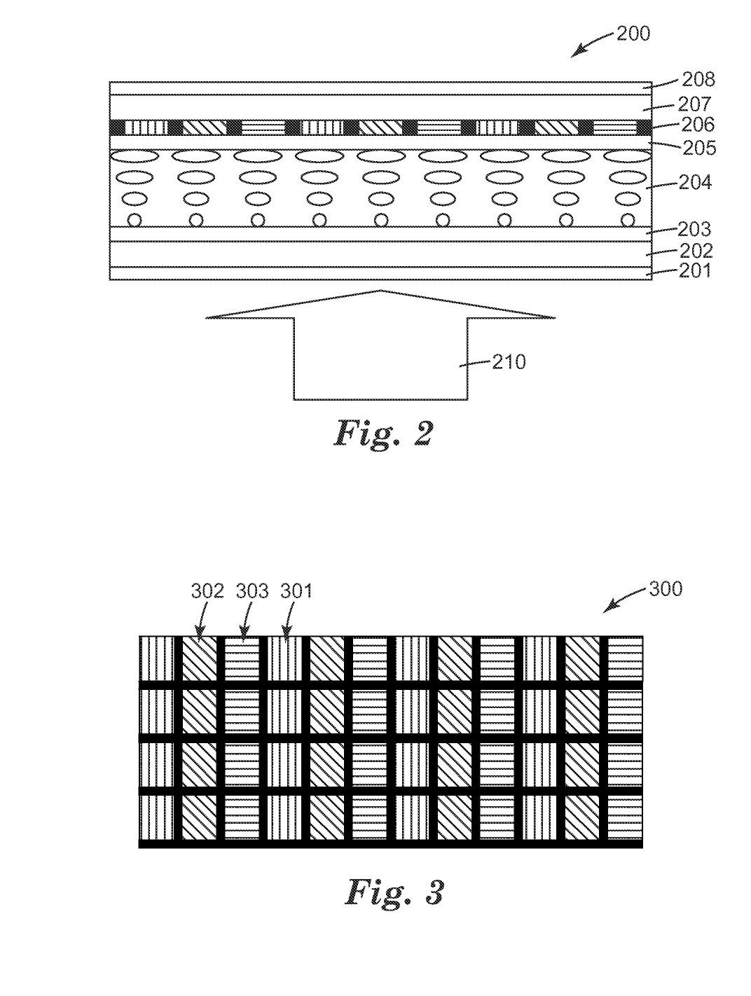

In a conventional display device, the color filter is used to filter the black light so as to represent the corresponding color. However, the color filter absorbs ⅔ energy of back light. The absorbed energy will be converted into heat or any other energy such that a large proportion of back light energy is wasted. FIG. 1 shows a cross-sectional schematic view 100 of a liquid crystal device with a photovoltaic cell according to the prior art. From the bottom, layers are as follows: 110 is a backlight module, 121 is a rear horizontal polarizer, 131 is a glass substrate, 140 is a pixel unit comprising pixel electrodes 151, 152, and 153, subpixels 141, 142, and 143, and common electrodes 161, 162, and 163. Photovoltaic unit 190 comprises, in addition, photovoltaic layers 181, 182, and 183, as well as photovoltaic electrodes 171, 172, and 173. Above this is barrier layer 180, upper glass substrate 132, front vertical polarizer 122, and glass screen 180. Ambient light 10 is transmitted through glass screen 180, and white light 15 is transmitted from backlight unit 110. FIG. 2 shows a structure of a common display device 200 which comprises a color filter layer 206.

The color filter generally comprises a black matrix and a color filter layer. Each set of red, green and blue three units (subpixels) compose a pixel for producing a different color. FIG. 3 is a top view of structure 300 of a color filter layer. In addition, in the prior display device combined with a solar cell, the solar cell, including so-called transparent solar cell, has a certain color. Such solar cell layer placed on a display device will absorb a portion of visible light so that the displaying effect is affected.

However, in the present invention, the above problem can be solved by integrating a solar cell panel comprising a photoelectric active material layer with RGB colors (hereinafter, abbreviated sometimes as the solar cell panel of the present invention) on the display unit.

Specifically, the display device of the present invention comprises a display unit and a solar cell panel integrated on the display unit, wherein the solar cell panel comprises a photoelectric material layer with RGB colors comprising red units, green units and blue units, wherein the red units, green units and blue units are arranged corresponding to pixel arrays in the display unit, and one or two of the red units, green units and blue units are made of a photoelectric active material.

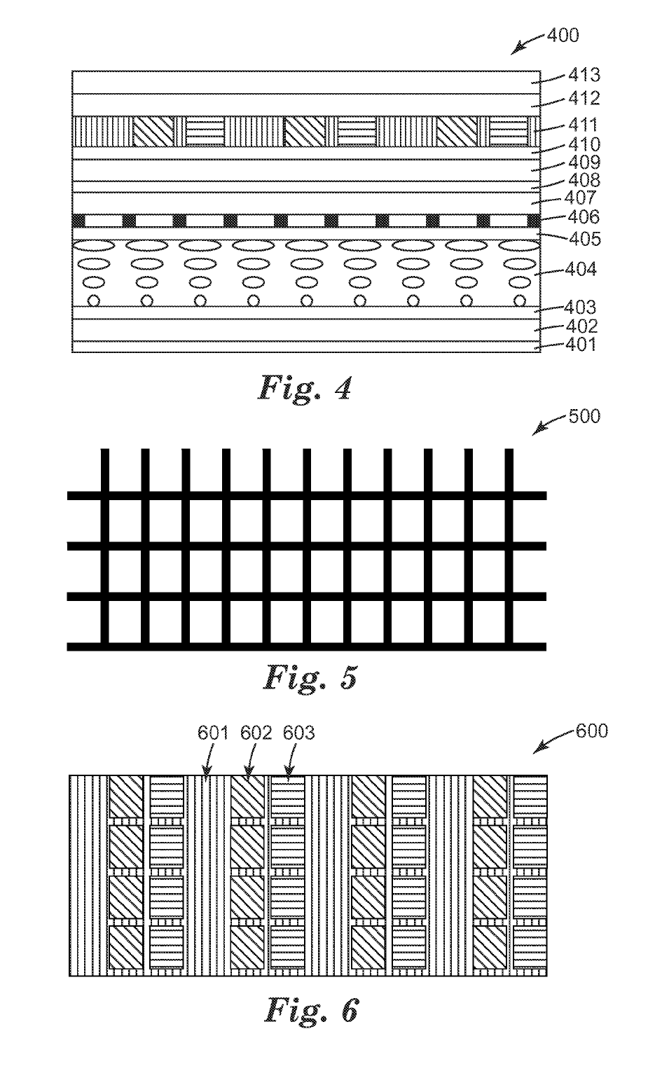

FIG. 4 is a schematic view 400 of a structure of a display device with the solar cell panel according to one embodiment of the present invention. As can be seen from this figure, the device has a display unit at the bottom and a solar cell panel at the top. In the display unit, the color filter layer is removed and only a black matrix remains. FIG. 5 is a schematic top view 500 of the black matrix of the present invention. FIG. 6 is a schematic top view 600 of the photoelectric active layer of the solar cell panel of the present invention. In FIG. 6, blue 603 and green 602 blocks represented by transverse lines-marked and oblique lines-marked blocks correspond to the blue and green subpixels of the previous color filter and color resist materials are also same as those of a common color filter. The remaining portion is covered by the red photoelectric active material represented by vertical lines-marked blocks 601.

The photoelectric active layer is so designed such that the current materials having higher photoelectric conversion efficiency, which can absorb a large proportion of blue light and green light in the visible light and is basically transparent to red light, can be used as a red color filter. Further, blue and green photoelectric active materials have generally lower conversion efficiency and thus are still made of common color resist materials.

Accordingly, the solar cell panel in the display device of the present invention can function like a color filter while producing electricity, so as to allow the omission of a color filter layer in the display device (eliminate the waste of the backlight energy) and further simplify the process and save the cost; and it can overcome the problem that the solar cell absorbs a portion of visible light so as to produce a certain color which affects the displaying effect.

Each of the components of the display device of the present invention and a method for producing the same are described hereinafter in detail.
1. Solar Cell Panel

The solar cell panel of the present invention is characterized in that the photoelectric active material layer is one consisting of red units, green units and blue units and having RGB colors, wherein the red units, green units and blue units are arranged corresponding to pixel arrays in the display unit, and one or two of the red units, green units and blue units are made of a photoelectric active material, and it is preferable that the red units are composed of a red photoelectric active material, and the green units and blue units are composed of green and blue resist materials, respectively.

In addition, the red units, green units and blue units of the photoelectric active material layer can cover not only the respective red units, green units and blue units of the common color filter but also the black matrix so that the effective area of the photoelectric active material layer is increased.

With the above configuration, merely one photoelectric active material layer is enough for replacing the common color filter so that the display device does not need an additional color filter.

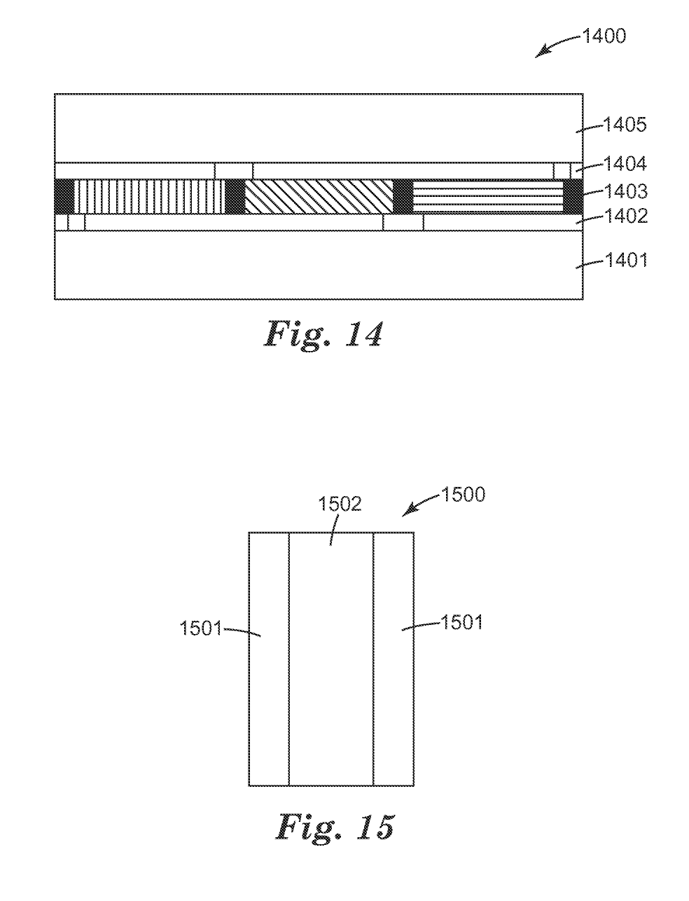

In the present invention, the black matrix used in the common color filter may remain in the display unit or may be disposed in the solar cell panel. When the black matrix is disposed in the solar cell panel, it may locate under the photoelectric active material layer or in the photoelectric active material layer. When the black matrix is disposed in the photoelectric active material layer, the black matrix can be made of a conductive material coated with an insulating adhesive. In the solar cell panel of the present invention, the photoelectric material layer is provided with transparent substrate layers at the two sides thereof, and a transparent conductive layer can be provided at a side of the transparent substrate layer facing the photoelectric material layer. As shown in FIGS. 12 and 13, the conductive material 1202 and 1302 coated with the insulating adhesive 1301 is provided between the two transparent conductive layers (for example, one transparent conductive layer is disposed as a transparent electrode layer, and the other is disposed as a hole transmission layer). Since the insulating adhesive 1301 separates the conductive material 1302, each of solar cell units is connected in the parallel connection. As shown in FIGS. 14 and 15, the conductive material 1402 and 1502 coated with the insulating adhesive 1501 is provided between the two transparent conductive layers, and several insulating separators are provided on the transparent conductive layers near the black matrix. These insulating separators can be formed by removing the transparent conductive material through a laser etching or mechanic reticle process. Since the insulating adhesive 1501 does not separate the conductive material 1502, each of solar cell units is connected in the series connection. It is well known in the circuit design that a larger output voltage can be obtained by providing a series-connected circuit or a larger output current can be obtained by providing a parallel-connected circuit. By optimizing the design of the solar cell circuit in the ways of FIGS. 12 and 14 separately or in combination according to the actual requirements, different output voltages and currents can be obtained so as to satisfy the need of different terminal application.

In order to prevent the opaque metal electrode from affecting the displaying effect and light absorbing efficiency, it is preferable that the solar cell panel of the present invention uses an organic solar cell with an inverted structure, that is, an organic solar cell with an inverted bulk heterojunction structure.

In an organic solar cell, two organic semiconductor materials are generally used to simulate an inorganic heterojunction solar cell, that is, bilayer film heterojunction type organic solar cell (Bilayer organic photovoltaic cell), which is the cell structure used in the US patent application No. 2010/0245731. The organic semiconductor material as the donor absorbs photons so as to produce hole-electron pairs, and after electrons are injected into the organic semiconductor material as the acceptor, the holes and electrons are separated. In this system, the electron donor is p type and the electron acceptor is n type, so that the holes and electrons are respectively transmitted to two electrodes whereby forming a photoelectric current. As compared with the silicon semiconductor, the interaction between organic molecules is much weaker, and the LUMOs and HOMOs between different molecules cannot be combined in the entire bulk phase to form a continuous conduction band and valence band. The transmission of the current carriers in the organic semiconductor is achieved by means of the mechanism of “transition” of charges between different molecules, which is macroscopically characterized by the fact that the mobility of the current carries thereof is much lower than that of the inorganic semiconductor. Meanwhile, when small organic molecules are excited by means of absorbing photons, they cannot work like the silicon semiconductor which produces free electrons in the conduction band and remains holes in the valence band. The small organic molecules excited by light will produce hole-electron pairs combined by static interaction, that is, so-called excitons. The lifetime of the exciton is limited and is generally on the order of millisecond or less. The electron and hole which are not completely separated will be recombined and release the absorbed energy. It is obvious that the exciton which is not separated into free electron and hole does not contribute to the photoelectric current. Therefore, the efficiency of exciton separation in the organic semiconductor has a critical influence on the photoelectric conversion efficiency of the cell.

As a modification, a bulk heterojunction photovoltaic cell has been proposed. The so-called bulk heterojunction is a bulk film formed by mixing donor and acceptor materials using co-evaporation or spin coating. The exciton produced at any position can arrive at the interface (that is, junction) of the donor and acceptor through a very short path, so that the efficiency of charge separation is improved. Meanwhile, the positive and negative current carriers formed at the interface can also arrive at the electrodes through a short path to offset the deficiency of the mobility of the current carriers.

The inverted bulk junction structure (that is, the structure used in the present invention) is based on the bulk heterojunction, but the positions of the hole transmission layer and the heterojunction layer are interchanged, so that the metal electrode layer of the cathode can be omitted due to the conductive property of the hole transmission layer, and the cell has better light transmissivity without compromising the conversion efficiency.

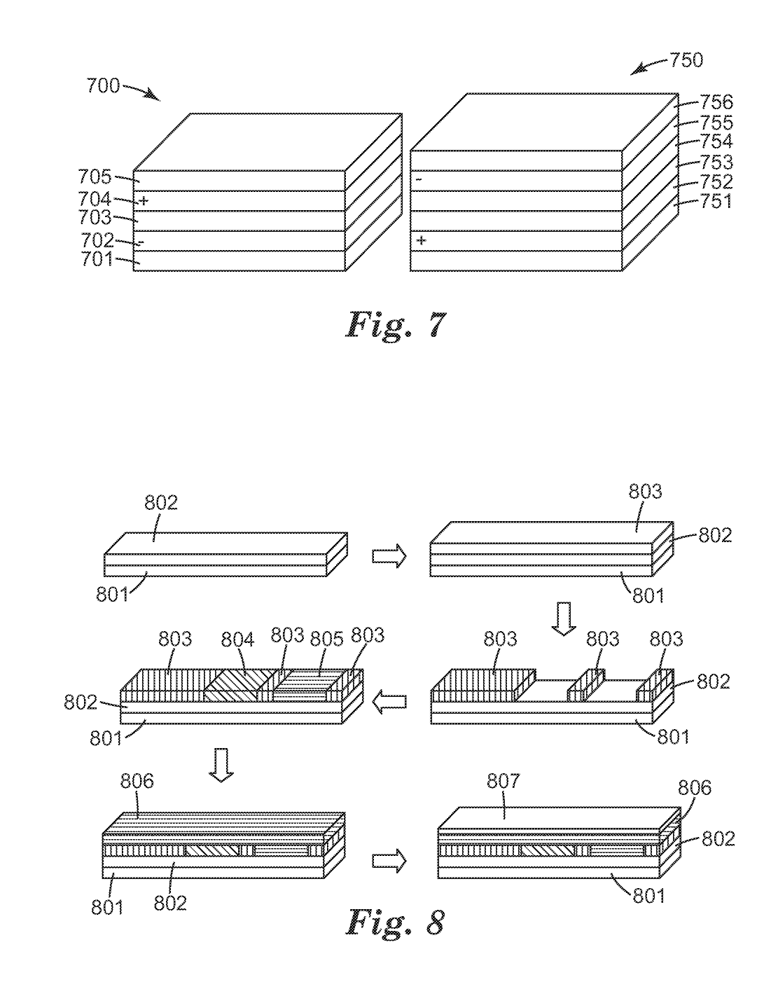

FIG. 7 shows a bulk heterojunction structure 700 and an inverted bulk heterojunction structure 750 of an organic solar cell. The solar cell with an inverted bulk heterojunction structure can avoid using a metal electrode so as to prevent the opaque metal electrode from affecting the displaying effect. In addition, the inverted structure can increase the absorbance of the outside light by the solar cell so as to improve the photoelectric conversion efficiency.

As a representative example, the solar cell panel of the present invention comprises a first transparent substrate, a transparent electrode layer, the photoelectric active material layer, a hole transmission layer and a second transparent substrate stacked in this order from bottom to top.

As a representative example, the solar cell panel of the present invention comprises a first transparent substrate, a transparent electrode layer, the photoelectric active material layer, a hole transmission layer, a metal grid layer and a second transparent substrate stacked in this order from bottom to top.

In the solar cell panel of the present invention, the first and second transparent substrates may be of any transparent material, for example, glass, PET (polyethylene terephthalate), PEN (polyethylene naphthalate), PC (polycarbonate), PS (polystyrene), PMMA (poly(methyl methacrylate)), PETG (ethylene glycol-modified polyethylene terephthalate), AS (acrylonitrile-styrene resin), BS (butadiene-styrene copolymer), MS (methyl methacrylate- styrene copolymer), MBS (methyl methacrylate-butadiene-styrene copolymer), ABS (acrylonitrile-butadiene-styrene plastic), PP (polypropylene) and PA (polyamide) and the like, and preferably glass or a flexible substrate such as PET.

The material of the red photoelectric active material layer may be P3HT:PC61BM (P3HT: poly(3-hexylthiophene); PC61BM: poly([6,6]-phenyl-C61-butyric acid methyl ester), P3HT:PC70BM (P3HT: poly(3-hexylthiophene)); PC70BM: poly([6,6]-phenyl-C71-butyric acid methyl ester), or PCDTBT:PC61BM (PCDTBT: polycarbazole conjugated polymer (poly[N-9′-heptadecanyl-2,7-carbazole-alt-5,5-(4′,7′-di-2-thienyl-2′,1′,3′-benzothiadiazole)])); PC61BM: poly([6,6]-phenyl-C61-butyric acid methyl ester)).

The blue resist material is obtained by dispersing a blue dye in a resin. The blue dye may be selected from the group consisting of phthalocyanine-based dyes, azo-based dyes, and anthraquinone-based dyes, and preferably, phthalocyanine-based dyes. The resin may be selected from the group consisting of an acrylic resin, an epoxy resin, and a styrene resin, and preferably, an acrylic resin.

The green resist material is obtained by dispersing a green dye in a resin. The green dye may be selected from the group consisting of phthalocyanine-based dyes, azo-based dyes, and anthraquinone-based dyes, and preferably, phthalocyanine-based dyes. The resin may be selected from the group consisting of an acrylic resin, an epoxy resin, and a styrene resin, and preferably, an acrylic resin.

The material of the hole transmission layer may be PEDOT:PSS (PEDOT: poly3,4-ethylenedioxythiophene); PSS: polystyrenesulphonate).

The transparent electrode layer may be a layer made of a transparent conducting material such as ITO (Indium tin oxide), FTO (fluorine doped tin oxide), ZnO (zinc oxide), silver nanowire coating layer or fullerene thin film.

The metal grid layer may be a grid layer made of a material such as silver, aluminium, copper and calcium.
2. Display Unit

The display unit in the display device of the present invention may be any display unit, including: a liquid crystal display unit, an electrophoresis type display unit, a plasma display unit, a LED display unit, an OLED display unit, a CRT display unit and the like. These display units do not comprise a color filter, that is, a color filter consisting of a black matrix and a color filter layer, but may comprise a black matrix itself.

The present invention is particularly applicable for a display device where the display unit is a liquid crystal display unit. The liquid crystal display unit comprises a transmissive liquid crystal display unit, a semi-transmissive/semi-reflective liquid crystal display unit, a reflective liquid crystal display unit and the like.

A typical structure of the liquid crystal display unit comprises a bottom polarizing plate, a bottom substrate (such as a glass layer), a bottom electrode layer, a liquid crystal layer, a top electrode layer, a top substrate (such as a glass layer) and a top polarizing plate laminated in this order. When the solar cell panel of the present invention is integrated with a liquid crystal display unit, the solar cell panel may be provided on the top polarizing plate or between the top substrate and the top polarizing plate.
3. Method for Producing the Display Device of the Present Invention

In the present invention, since the solar cell panel is integrated on the display unit rather than in the display unit, the method for producing the display device of the present invention is relatively simple, and it only needs to affix the produced solar cell panel onto the display unit in such a way that the pattern of the photoelectric active material layer is aligned with that of the black matrix. The solar cell panel is affixed onto the display unit at the side of the first transparent substrate layer or second transparent substrate layer.

The production process of the solar cell panel of the present invention is also relatively simple. As shown in FIG. 8, an ITO layer 802 is first produced on a transparent substrate 801 (which may be a glass substrate or s flexible substrate such as PET), then a layer of the red photoelectric active material 803 is deposited on the ITO layer 802, after that, the red active material 803 at the sites of the blue and green units (subpixels) is removed by exposure via a mask and blue 805 and green 804 resist materials are filled at the corresponding positions, then a layer of hole transmission material 806 is coated, and finally a layer of transparent substrate material 807 is applied for encapsulating.

When the solar cell panel is assembled to the display unit, it would be careful to match the units with the black matrix. Meanwhile, they can be bonded with an optical class adhesive (OCA adhesive) to improve the displaying effect of the device.

In the method for producing the display device of the present invention, the two substrates of the solar cell panel may be any transparent material such as glass, but it is preferably a transparent flexible material (such as a PET substrate) so that the mass and rapid production may be performed using a roll-to-roll technology, furthermore, as compared with a rigid cell panel such as glass, a flexible cell panel is more easily affixed to the display device so that the production process can be simplified.

As the outmost layer of the solar cell panel, the second transparent substrate may be formed of a curable transparent resin (for example, an UV-curable resin) or other suitable transparent insulating material so as to encapsulate and protect the entire cell panel.

In addition, in the step of removing the red photoelectric active material at the sites of the blue units and green units, the method of exposure via a mask may be adopted.

The transparent electrode layer, red photoelectric active material layer, color resist materials and hole transmission material layer are deposited by a vacuum deposition process or a wet deposition process, wherein the wet deposition process comprises spin coating, spray coating, casting, inkjet printing, screen printing or roll-to roll coating process.

In the method for producing the display device of the present invention, the solar cell layer and display panel layer can be separately produced such that the ratio of defective products in the production can be effectively reduced.

### EXAMPLES

Hereinafter, the present invention is described in more detail by way of the examples which are only exemplificative and would not be understood as the limitations on the scope of the present invention.

### Example 1

### (the Black Matrix was Iocated on the Bottom Surface of the Top Substrate of the Display Unit)

The production of the display unit:

The liquid crystal display unit where the black matrix was located on the bottom surface of the top substrate was produced in the following way:
1. An ITO bottom electrode layer with a TFT (thin film transistor) was formed on the bottom substrate by a method such as etching, sputtering or deposition or the like;
2. A black matrix whose material was metallic chrome was formed on the bottom surface of the top glass substrate by a photolithography process;
3. A top electrode layer whose electrode material was ITO was formed at the bottom of the black matrix by a sputtering process;
4. A liquid crystal cell was formed by assembling the top and bottom substrates, wherein a liquid crystal layer was formed by vacuum suction;
5. A polarizing film as the bottom polarizing plate was affixed on the bottom surface of the bottom glass substrate, wherein the bottom polarizing plate was a composite consisting of polyvinyl alcohol (PVA) stretched film and cellulose acetate (TAC) film;
6. A polarizing film as the top polarizing plate was affixed on the top surface of the top glass substrate, wherein the top polarizing plate was a composite consisting of polyvinyl alcohol (PVA) stretched film and cellulose acetate (TAC) film,
whereby a display unit 1 was produced.

The production of the solar cell panel:

A PET flexible substrate with a thickness of about 0.75 mm was used as the first transparent substrate. An ITO layer with a thickness of about 150 nm was formed on the first substrate by vacuum deposition, and then a layer of red photoelectric active material (P3HT:PC61BM, LT-S909 LT-S905, Luminescence Technology Corp.) with a thickness of about 200 nm was coated on the ITO layer by spin coating. Then, the red active material at the sites of the blue and green units was removed by exposure via a mask. The blue and green resist materials (which are separately obtained by dispersing blue CuPC dye (LT-E201, Luminescence Technology Corp.) and green ZnPC dye (LT-S906, Luminescence Technology Corp.) in an acrylic resin (6530B-40, Chang Xing Chemical Material LTD.)) were filled at the corresponding positions on ITO layer by an inkjet printing process. After drying the dyes, a hole transmission layer (PEDOT:PSS, AI4083, Luminescence Technology Corp.) with a thickness of about 25 nm was formed by spin coating. A silver grid layer was deposited on the hole transmission layer by a thermal deposition process.

Finally, the encapsulation was performed with a PET film (3 mil, 3M) produced by 3M corporation, so as to produce the solar cell panel 1.

### The Integration of the Display Unit and the Solar Cell Panel

The solar cell panel 1 was placed above the display unit 1 such that the pattern of RGB units on the solar cell panel 1 was aligned with that of the black matrix of the display unit 1, and the solar cell panel 1 and the display unit 1 were bonded with an OCA (8172, 3M) to produce the display device 1 having a structure shown in FIG. 4.

### Example 2

### (The Black Matrix was Located on the Top Surface of the Bottom Electrode of the Display Unit)

The display unit was produced in the same manner of the example 1 to produce the display unit 2, except that the black matrix was formed on the top surface of the bottom electrode of the display unit.

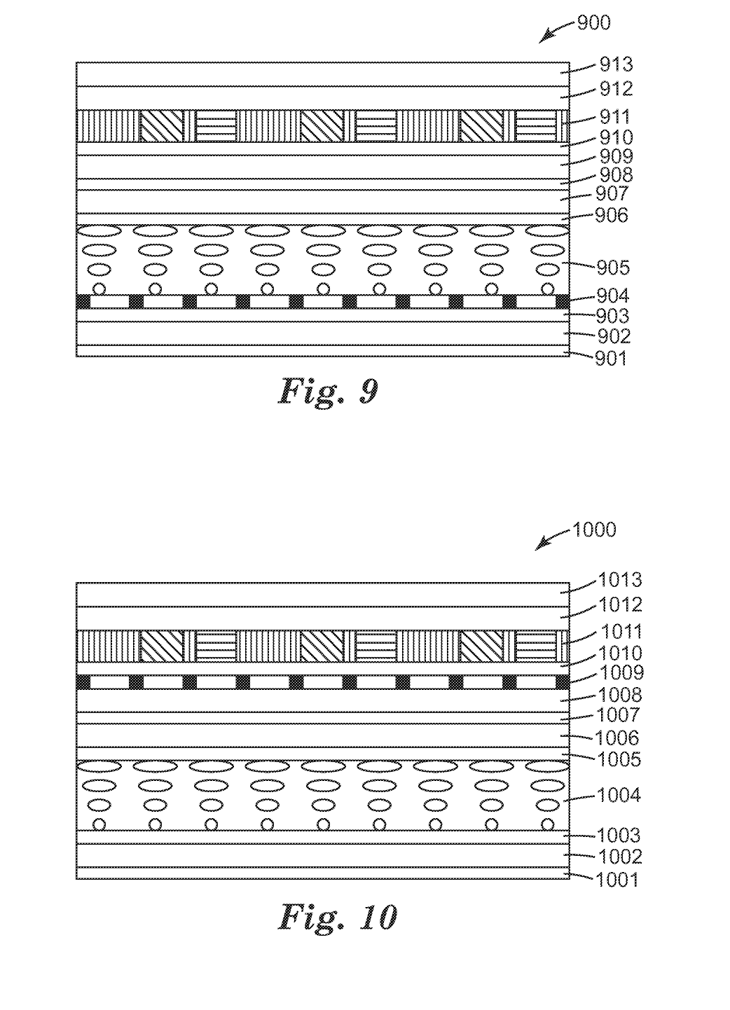

The display unit 2 and the solar cell panel 1 were integrated in the same manner of the example 1 to obtain the display device 2 having a structure shown in FIG. 9.

### Example 3

### (The Black Matrix was Located on the Top Surface of the First Substrate of the Solar Cell Panel)

The display unit and the solar cell panel were produced in the same manner of the example 1, except that the step of forming the black matrix was omitted in the production of the display unit, and in the production of the solar cell panel, a black matrix was firstly formed on the first substrate and then an ITO layer was formed, so as to obtain the display unit 3 and solar cell panel 2, respectively.

The display unit 3 and the solar cell panel 2 were integrated in the same manner of the example 1 to obtain the display device 3 having a structure shown in FIG. 10.

### Example 4

### (The Black Matrix was Located in the Photoelectric Active Material Layer of the Solar Cell Panel)

The display unit and the solar cell panel were produced in the same manner of the example 3, except that in the production of the solar cell panel, the black matrix was formed in the photoelectric active material layer, so as to obtain the display unit 3 and solar cell panel 3, respectively.

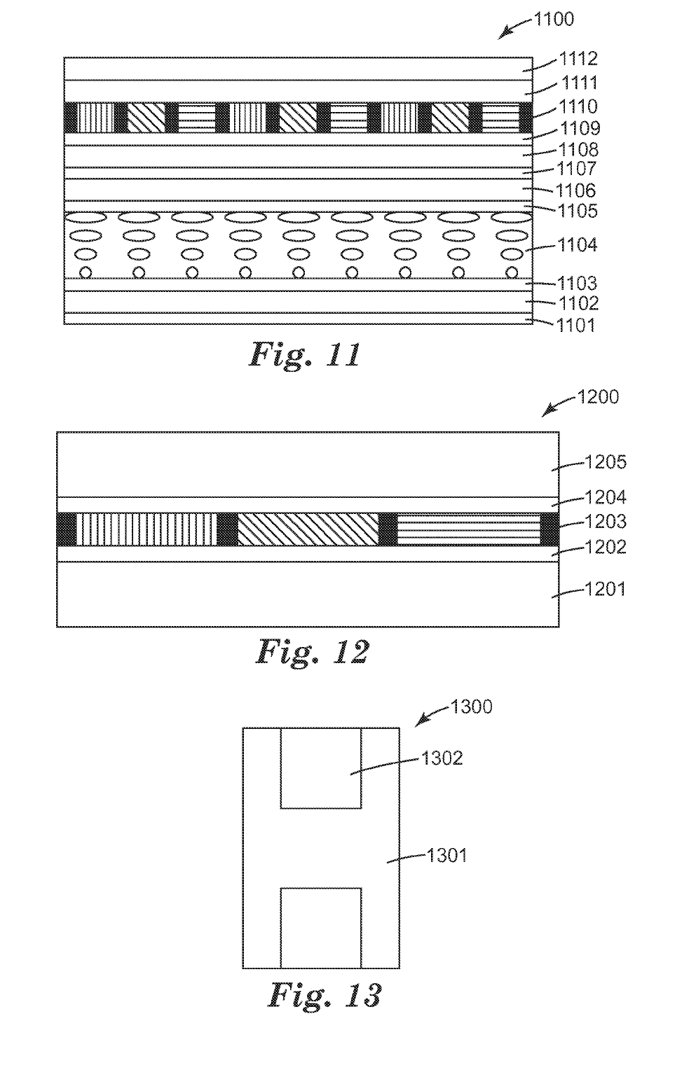

The display unit 3 and the solar cell panel 3 were integrated in the same manner of the example 1 to obtain the display device 4 having a structure shown in FIG. 11.

### Example 5

### (The Black Matrix was Located in the Photoelectric Active Material Layer of the Solar Cell Panel)

The display unit and the solar cell panel were produced in the same manner of the example 4, except that the black matrix (as shown in FIG. 13) was formed in the photoelectric active material layer and the entire solar cell is produced in the parallel connection as shown in FIG. 12, thereby obtaining the solar cell panel 4.

The display unit 3 and the solar cell panel 4 were integrated in the same manner of the example 1 to obtain the display device 5 having a structure shown in FIG. 11.

### Example 6

### (The Black Matrix was Located in the Photoelectric Active Material Layer of the Solar Cell Panel)

The display unit and the solar cell panel were produced in the same manner of the example 4, except that the black matrix (as shown in FIG. 15) was formed in the photoelectric active material layer and the entire solar cell is produced in the series connection as shown in FIG. 14, thereby obtaining the solar cell panel 5.

The display unit 3 and the solar cell panel 5 were integrated in the same manner of the example 1 to obtain the display device 6 having a structure shown in FIG. 11.

### Example 7

### (The Black Matrix was Located in the Photoelectric Active Material Layer of the Solar Cell Panel)

The display unit and the solar cell panel were produced in the same manner of the example 4, except that the black matrix was formed in the photoelectric active material layer and the series and parallel connection design of the entire solar circuit was optimized in the combined ways of FIGS. 12 and 14 according to the actual requirements, thereby obtaining the solar cell panel 6.

The display unit 3 and the solar cell panel 6 were integrated in the same manner of the example 1 to obtain the display device 7 having a structure shown in FIG. 11.

### Comparative Example 1

The display device was produced in the same manner of the example 1 except that, in the photoelectric active material layer of the solar cell panel, a blue photoelectric active material (CuPc: BCP (copper phthalocyanine complex, LT-E201): Bathocuproine (2,9-Dimethyl-4,7-diphenyl-1,10-phenanhroline, LT-E304), Luminescence Technology Corp.)) and a green photoelectric active material (ZnPc: BCP (zinc phthalocyanine, LT-S906): Bathocuproine (2,9-Dimethyl-4,7-diphenyl-1,10-phenanhroline, LT-E304), Luminescence Technology Corp.) were used in place of the blue and green resist materials so as to obtain a comparative display device. The display device had a poorer displaying effect and much lower color representability than the display devices of the above examples 1-7.

### INDUSTRY APPLICABILITY

The display device integrated with the solar cell panel of the present invention can allow the omission of the conventional color filter, and the integrated solar cell panel can convert a portion of absorbed unnecessary backlight and ambient light entered into the display device from outside into electric power while functioning as a color filter, which greatly increases the capability of the cell of the portable device, as a result, it can not only decrease the weight of the device but also obtain the comparable or higher use duration.

The display device integrated with the solar cell panel of the present invention is applicable for various applications such as outside electronic billboard, and allows the use of the outside electronic billboard at the place where power source is not available such as in the field.

1. A solar cell panel integrated on a display unit, comprising:
a photoelectric material layer with RGB colors, said photoelectric material layer comprising red units, green units and blue units,
wherein the red units, green units and blue units are arranged corresponding to pixel arrays in the display unit, and
one or two of the red units, green units and blue units are made of a photoelectric active material.

2. The solar cell panel according to claim 1, wherein the solar cell panel is integrated on a surface of the display unit.

3. The solar cell panel according to claim 1, wherein the red units are made of a photoelectric active material.

4. The solar cell panel according to claim 1, wherein the red units are made of one or more materials selected from the group consisting of P3HT:PC61BM (poly(3-hexylthiophene): poly([6,6]-phenyl-C61-butyric acid methyl ester)), P3HT:PC70BM (poly(3-hexylthiophene): poly([6,6]-phenyl-C71-butyric acid methyl ester)) and PCDTBT:PC61BM (poly[[9-(1-octylnonyl)-9H-carbazole-2,7-diyl]-2,5-thiophenediyl-2,1,3-benzothiadiazole-4,7-diyl-2,5-thiophenediyl]:poly([6,6]-phenyl-C61-butyric acid methyl ester)).

5. The solar cell panel according to claim 1, which further comprises a first transparent substrate layer and a second transparent substrate layer provided at the two sides of the photoelectric material layer, respectively.

6. The solar cell panel according to claim 5, wherein the first and second transparent substrate layers are of one or more selected from the group consisting of glass, PET, PEN, PC, PS, PMMA, PETG, AS, BS, MS, MBS, ABS, PP, and PA.

7-12. (canceled)

13. The solar cell panel according to claim 1, which has a structure of inverted bulk heterojunction.

14. The solar cell panel according to claim 5, which further comprises a black matrix.

15. The solar cell panel according to claim 14, wherein the black matrix is provided in the photoelectric material layer.

16. The solar cell panel according to claim 15, wherein the black matrix is made of a photoelectric active material.

17. The solar cell panel according to claim 15, wherein the black matrix is made of a conductive material coated with an insulating adhesive.

18. The solar cell panel according to claim 17, wherein the insulating adhesive is selected from the group consisting of acrylate-based, epoxy-based and polyurethane-based adhesives.

19. The solar cell panel according to claim 17, wherein the conductive material is a conductive metal.

20. (canceled)

21. A solar cell panel integrated on a display unit, comprising:
a photoelectric material layer with RGB colors comprising red units, green units and blue units, wherein the red units, green units and blue units are arranged corresponding to pixel arrays in the display unit, and the red units are made of a photoelectric active material;
a first transparent substrate layer and a second transparent substrate layer provided at the two sides of the photoelectric material layer, respectively;
a transparent electrode layer provided between the first transparent substrate layer and the photoelectric material layer; and
a hole transmission layer provided between the second transparent substrate layer and the photoelectric material layer.

22. The solar cell panel according to claim 21, wherein the solar cell panel comprising a metal grid layer provided between the hole transmission layer and the second transparent substrate layer, at a position corresponding to the boundaries between the red units, green units and blue units.

23. A display device comprising a display unit and the solar cell panel according to claim 1.

24. The display device according to claim 23, wherein the display unit is a liquid crystal display unit, an electrophoresis type display unit, an interference and modulation type (IMOD) display unit, an electrical soakage type display unit, a plasma display unit, a LED display unit, an OLED display unit or a CRT display unit.

25-27. (canceled)

28. The display device according to claim 23, wherein the display device comprises a black matrix provided in the display unit.

29. A method for producing the solar cell panel according to claim 21, comprising the steps of:
forming a transparent electrode layer on a first transparent substrate;
depositing a layer of red photoelectric active material on the transparent electrode layer;
then removing the red photoelectric active material at the sites of blue units and green units and filling blue and green resist materials at the corresponding positions;
coating a layer of hole transmission material; and
finally forming a second transparent substrate with a transparent insulating material.

30. A method for producing the solar cell panel according to claim 22, comprising the steps of:
forming a transparent electrode layer on a first transparent substrate;
depositing a layer of red photoelectric active material on the transparent electrode layer;
then removing the red photoelectric active material at the sites of blue units and green units and filling blue and green resist materials at the corresponding positions;
coating a layer of hole transmission material;
then depositing a layer of metal grid; and
finally forming a second transparent substrate with a transparent insulating material.

31-35. (canceled)
